(19) United States
(12) Patent Application Publication
(10) Pub. No.: US 2017/0239756 A1
(43) Pub. Date: Aug. 24, 2017

(54) LASER MANUFACTURING OF SOLDER PREFORMS

(71) Applicant: Materion Corporation, Mayfield Heights, OH (US)

(72) Inventors: Ramesh Kothandapani, Singapore (SG); SinLi Tan, Johor (MY); Chee Kong Lee, Singapore (SG)

(73) Assignee: Materion Corporation

(21) Appl. No.: 15/435,856

(22) Filed: Feb. 17, 2017

Related U.S. Application Data
(60) Provisional application No. 62/297,258, filed on Feb. 19, 2016.

(51) Int. Cl. B23K 35/02; B23K 35/30; B23K 26/38; B23K 26/40; H01L 23/10; B23K 1/19; C22C 5/02; H01L 21/48; H01L 23/053; B23K 35/26; B23K 26/16

(52) U.S. Cl. CPC B23K 35/0222; B23K 35/268; B23K 35/3013; B23K 26/38; B23K 26/40; B23K 26/16; B23K 1/19; C22C 5/02; H01L 21/4817; H01L 23/053; H01L 23/10; B23K 2203/52

(57) ABSTRACT

Methods of making solder preforms are disclosed. A ribbon of raw material is received, and a first annular solder preform is formed by laser cutting the ribbon. The edges of the first annular solder preform can then be cleaned. The cutout section removed from the middle of the first annular solder preform can then be laser cut to form a second annular solder preform that is smaller than the first annular solder preform.

### CROSS-REFERENCE TO RELATED APPLICATIONS

This application claims priority to U.S. Provisional Patent Application Ser. No. 62/297,258, filed on Feb. 19, 2016, which is fully incorporated by reference herein.

### BACKGROUND

The present disclosure relates to solder preforms used for ceramic package hermetic sealing applications. More specifically, processes for making solder preforms which increase the usage of raw material, reduce defects, and result in shorter lead times are described herein, as are the solder preforms formed thereby and electronic packages including such solder preforms.

Solder preforms are typically made by a stamping tool which stamps out solder preforms of a given size from a ribbon of raw material. The stamping tool is also known as a compound die. The compound die performs two actions concurrently, such as cutting an inner peripheral line and an outer peripheral line of the annular preform.

When the solder preform is formed with a stamping tool, only a small amount of the ribbon of raw material is used for production. The raw material adjacent the solder preform and the inner center cutout section of the preform are unused and must be refined or re-melted prior to being sent through the stamping tool again. This adds to additional cost. Furthermore, accurate molds with tight tolerances and adequate alignment are required to make stamping tools capable of producing acceptable solder preforms. The stamping tool also requires periodic maintenance that takes the production line out of service. This adds to production costs and reduces the manufacturing efficiency of solder preforms.

Some additional issues can arise when stamping tools are used to form solder preforms. First, when a solder preform having a new or different size is requested, a new stamping tool generally has to be fabricated. The lead time to fabricate each stamping tool can be as long as six to eight weeks. If the dimensions of a stamping tool are incorrect after fabrication, a new tool has to be refabricated, resulting in a loss of time and cost. Second, stamping tools can create raised edges or small pieces of material known as burrs which remain attached to the edges of the solder preform after stamping. Burrs can interfere with the sealing efficacy of the solder preform and may cause cracks to form in the solder. Deburring processes undesirably add to productions costs for forming solder preforms. It would be desirable to provide methods that minimize these problems.

### BRIEF DESCRIPTION

The present disclosure relates to methods of making solder preforms for use in hermetic sealing of electronic packages. A ribbon of raw material is provided. A first annular solder preform is formed by laser cutting the ribbon, with an exterior peripheral cutting edge defining an outer perimeter of the first annular solder preform and an interior peripheral cutting edge defining an inner perimeter of the first annular solder preform. The exterior peripheral cutting edge and the interior peripheral cutting edge of the first annular solder preform can then be cleaned.

In some embodiments, the ribbon of raw material is formed from a gold-tin alloy having about 80 wt % gold and about 20 wt % tin.

In further embodiments, the cleaning is performed by ultrasonically removing carbon on the exterior peripheral cutting edge and the interior peripheral cutting edge of the annular solder preform.

As desired, additional annular solder preforms can be laser cut from an inner cutout section of the first annular preform. The inner cutout section typically has an outer perimeter defined by the interior peripheral cutting edge of the first annular solder preform. The annular solder preforms can be in the shape of a square, rectangle, or disc.

Also disclosed in various embodiments are annular solder preforms prepared by: receiving a ribbon of raw material; laser cutting the ribbon along an exterior peripheral cutting edge and an interior peripheral cutting edge; and cleaning the exterior peripheral cutting edge and the interior peripheral cutting edge to obtain the annular solder preform.

The raw material can be a gold-tin alloy. An outer perimeter of the annular solder preform can be in the shape of a square having a length and a width of about 0.3 inches, and an inner perimeter of the annular solder preform is in the shape of a square having a length and a width of about 0.25 inches. The annular solder preform can be in the shape of a square, rectangle, or disc.

The methods may further include a method of using an annular solder preform in a frame lid assembly. An annular solder preform is tack welded to a cover lid having a first surface, a second surface, and a sidewall joining the first surface and second surface together. The annular solder preform is melted to fuse the cover lid to an insulating base that is shaped to include a cavity. The annular solder preform is made by laser cutting a ribbon of raw material in the appropriate shape and size. An exterior peripheral cutting edge defines an outer perimeter of the annular solder preform and an interior peripheral cutting edge defines an inner perimeter of the annular solder preform.

The cover lid can be made from beryllium-copper, molybdenum, bronze, glass, an iron-nickel-cobalt alloy, or a ceramic selected from the group consisting of alumina (Al2O3), beryllia (BeO), aluminum nitride (AlN), zirconia toughened alumina (ZTA), SiC, and Si₃N₄.

A second annular solder preform can be laser cut from the inner cutout section of the first annular solder preform. That second annular solder preform can be tack welded to a second cover lid having a first surface, a second surface, and a sidewall joining the first surface and second surface together. The second annular solder preform is then heated and melted. The second annular solder preform can then fuse the second cover lid to a second insulating base shaped to include a cavity.

Also disclosed herein are annular solder preforms which include a laser cut exterior peripheral cutting edge defining an outer perimeter of the annular solder preform and a laser cut interior peripheral cutting edge defining the inner perimeter of the first annular solder preform. The annular solder preform is formed from an alloy having about 80 wt % gold and about 20 wt % tin.

A second annular solder preform can be laser cut from the inner cutout section of the first annular solder preform. The annular solder preforms can be in the shape of a square, rectangle, or disc.

Also disclosed herein are methods of making multiple solder preforms from a single ribbon, comprising: receiving a ribbon of raw material formed from an alloy having about 80 wt % gold and about 20 wt % tin; forming a first annular solder preform by laser cutting the ribbon along an exterior peripheral cutting edge and an interior peripheral cutting edge, the interior peripheral cutting edge defining an outer perimeter of an inner cutout section; and laser cutting a second annular solder preform from the inner cutout section of the first annular solder preform.

These and other non-limiting characteristics of the disclosure are more particularly disclosed below.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 is a top view of a ribbon of raw material illustrating a conventional stamping method for forming annular solder preforms.

FIG. 2 is a top view of a ribbon illustrating the concept for making multiple annular solder preforms of different sizes from a single ribbon of raw material.

FIGS. 3A-3E are schematic illustrations of various steps of a method for laser cutting multiple annular solder preforms having a square shape. FIG. 3A shows the ribbon. FIG. 3B shows the exterior peripheral cutting edge. FIG. 3C shows the interior peripheral cutting edge. FIG. 3D shows the second annular solder preform being formed in the center cutout portion of the first annular solder preform. FIG. 3E shows the dimensions of the two annular solder preforms.

FIG. 4 is a perspective view of an annular solder preform.

FIGS. 5A-5D are schematic illustrations of various steps of a method for laser cutting multiple annular solder preforms having a circular shape. FIG. 5A shows the ribbon. FIG. 5B shows the exterior peripheral cutting edge. FIG. 5C shows the interior peripheral cutting edge. FIG. 5D shows the second annular solder preform being formed in the center cutout portion of the first annular solder preform.

FIG. 6A is a picture of a solder preform before cleaning (left side) and a solder preform after cleaning (right side) before a melt test.

FIG. 6B is a picture of the two solder preforms of FIG. 6A after the melt test.

FIG. 7 is a side cross-sectional view of a conventional electronic package including an annular solder preform of the present disclosure.

FIG. 8 is an exploded perspective view of the conventional electronic package of FIG. 7.

FIG. 9A is a perspective view of a cover lid/plate showing the seal ring. FIG. 9B is a top view of the plate of FIG. 9A. FIG. 9C is a side view of the plate of FIG. 9A.

FIG. 10A is an exploded view showing the annular solder preform being tack welded to the cover lid/plate.

FIG. 10B is a top view of the cover lid/plate and solder preform of FIG. 10A.

### DETAILED DESCRIPTION

A more complete understanding of the processes and apparatuses disclosed herein can be obtained by reference to the accompanying drawings. These figures are merely schematic representations based on convenience and the ease of demonstrating the existing art and/or the present development, and are, therefore, not intended to indicate relative size and dimensions of the assemblies or components thereof.

The present disclosure may be understood more readily by reference to the following detailed description of desired embodiments and the examples included therein. In the following specification and the claims which follow, reference will be made to a number of terms which shall be defined to have the following meanings.

The singular forms “a,” “an,” and “the” include plural referents unless the context clearly dictates otherwise.

Numerical values in the specification and claims of this application should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable (for example, the range of “from 2 grams to 10 grams” is inclusive of the endpoints, 2 grams and 10 grams, and all the intermediate values).

As used herein, approximating language, such as “about” and “substantially,” may be applied to modify any quantitative representation that may vary without resulting in a change in the basic function to which it is related. The modifier “about” should also be considered as disclosing the range defined by the absolute values of the two endpoints. For example, the expression “from about 2 to about 4 ” also discloses the range “from 2 to 4.” The term “about” may refer to plus or minus 10% of the indicated number.

The term “room temperature” refers to a range of from 20° C. to 25° C.

The terms “annular” or “annulus” refer to a planar shape formed by the area between two concentric shapes whose edges are parallel to each other. These terms can refer, for example to the ring shape bounded by two concentric circles, or to the shape contained between two squares with a common center whose sides are parallel to each other.

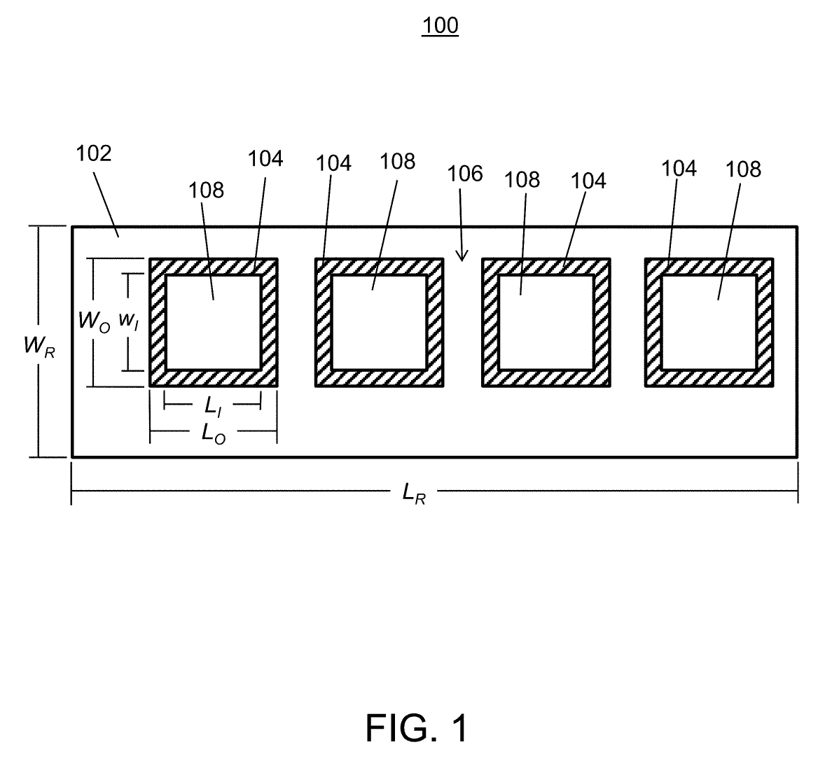

A conventional stamping method 100 for forming an annular solder preform is illustrated in FIG. 1. The ribbon 102 is made from a raw metal alloy material such as a gold-tin alloy (e.g. 80Au-20Sn). Initially, the ribbon fabrication starts by casting the gold tin-alloy to form a casting having a fine and largely uniform grain structure. The casting can then be rolled and trimmed to form a gold-tin sheet or ribbon having a desired thickness, length, and width. The ribbon is then stamped to form solder preforms 104 therefrom. The preforms are then cleaned, which may include a deburring process to remove undesirable ridges or deformations which have formed along the stamped edges.

The conventional method of stamping the ribbon into solder preforms results in the ribbon portion 106 (outside of the solder preforms) and inner cutout portions 108 (from the center of each solder preform) being unused after the stamping process. These portions 106, 108 can be refined or re-melted to form a new ribbon of material which can then be passed through the stamping tool/die again to produce more annular solder preforms.

The usage of the gold-tin ribbon in this conventional stamping method for forming annular solder preforms can be calculated. Referring again to FIG. 1, the ribbon 102 has a hypothetical length L_{R} of about 340 inches and a hypothetical width W_{R} of about 0.5 inches, resulting in a total ribbon area of 170 square inches (in²). One-thousand annular square preforms 104 having an outer width Wₒ and outer length Lₒ of about 0.300 inches, and an inner width Wₗ and inner length Lₗ of about 0.250 inches can be stamped from a ribbon having these dimensions. The total area of a single annular preform at these dimensions is about 0.028 in², and the total area of all one-thousand preforms is about 28 in². Thus, the one thousand annular preforms use only about 16% (i.e. 28/170) of the total ribbon area in the initial stamping process. The total area of all center cutout portions 108 is about 62.5 in², which represents about 37% of the total ribbon area. The remaining ribbon portion 106 is unused and represents about 47% of the total ribbon area. As a result, about 84% of the total ribbon area remains unused in a single pass through the stamping tool.

The conventional stamping process illustrated in FIG. 1 can be replaced with a laser cutting process according to the present disclosure. No modifications to the raw material fabrication process are necessary. That is, ribbon fabrication still begins with casting the gold tin-alloy with a fine and largely uniform grain structure, followed by rolling and trimming to form a ribbon having a desired thickness, length, and width. After the ribbon of raw material is produced, it can be rolled up into a spool form, which is then used as the input to a laser cutting machine that cuts the ribbon into solder preforms. After cutting, a cleaning process is applied to the preforms to remove carbon built up along the cutting edges.

Advantageously, the preforms should not be deformed, damaged, or melted during the cutting process. The precise laser cutting process maintains the original composition of the gold-tin alloy without changing the alloy's chemical phase. In addition, the laser cutting produces burr-free cutting edges without compromising alloy quality.

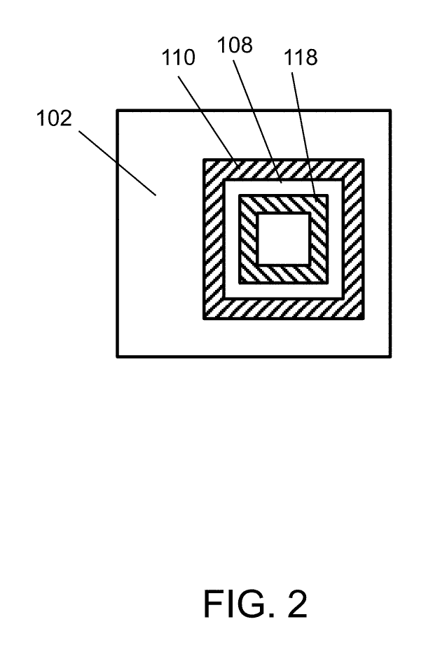

FIG. 2 is a top view of a ribbon 102 illustrating the processes of the present disclosure. Illustrated here is a ribbon of raw material 102, from which a first annular solder preform 110 is formed by laser cutting. Forming the first annular solder preform results in an inner or center cutout portion 108. A second annular preform 118 can then be laser cut out of the inner cutout portion 108 of the first annular preform. As a result, the outer dimensions of the second annular preform are necessarily smaller than the inner dimensions of the first annular preform.

The present disclosure is not limited to laser cutting only two annular preforms 110, 118 out of the ribbon as shown in FIG. 2. Depending on the dimensions, it is possible for another annular preform to be cut out of the inner cutout sections of each prior annular preform. It should also be understood that any number of annular preforms having multiple dimensions can be cut out of the ribbon in a single pass, depending on the size of the ribbon of raw material and the desired dimensions of the annular preforms. Compared to the conventional stamping method illustrated in FIG. 1, more of the material of the ribbon of FIG. 2 is converted into a final annular solder preform for use with a frame lid assembly. In particular, the center cutout portions of each annular preform are used to form additional preforms, advantageously maximizing usage of the ribbon, reducing manufacturing costs, and shortening lead-time.

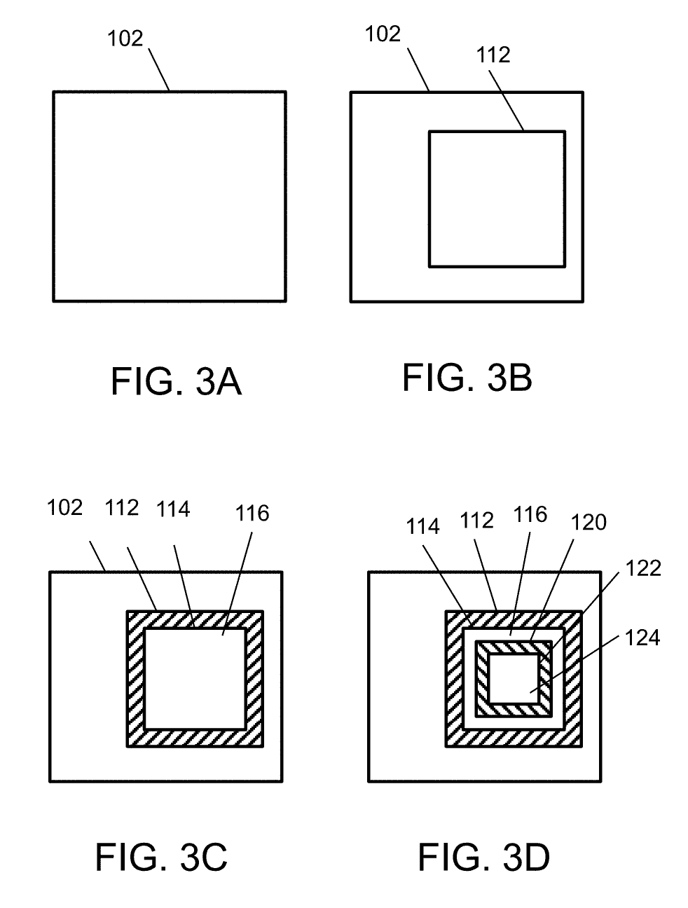

In FIGS. 3A-3E, a method for laser cutting multiple annular solder preforms in the form of squares is illustrated. First, in FIG. 3A, the ribbon of raw material 102 is received in the laser cutting machine. Next, in FIG. 3B, the process of obtaining a first annular solder preform begins by cutting an exterior peripheral cutting edge 112. The exterior peripheral cutting edge defines an outer perimeter of the first annular solder preform. Next, in FIG. 3C, an interior peripheral cutting edge 114 is cut. Interior peripheral cutting edge defines an inner perimeter of the first annular solder preform 110. The interior peripheral cutting edge also defines an outer perimeter of the inner cutout section 116. Usually, the exterior cutting edge 112 is cut before the interior cutting edge 114, but this order can be reversed if desired.

A second annular solder preform is then formed from the inner cutout section 116. Again, any additional solder preforms fabricated from the inner cutout section 116 will necessarily be smaller than the first annular solder preform. This can be done with the inner cutout section 116 still located within the first annular preform 110, or the inner cutout section 116 can be removed from the first annular preform and then processed.

To form the second annular preform 118, as seen in FIG. 3D, a second exterior peripheral cutting edge 120 and a second interior peripheral cutting edge 122 formed by the laser cutting machine within the inner cutout section 116, with the second annular preform 118 being defined between these two cutting edges 120, 122. A second cutout section 124 is also formed by the second cutting edge 122.

It is contemplated that sometimes the interior peripheral cutting edge 114 of the first annular solder preform could also serve as the second exterior peripheral cutting edge 120. However, it is believed that such situations will rarely occur.

The first annular solder preform 110 and the second annular solder preform 118 are then removed from the ribbon 102. The annular solder preforms 110, 118 can then be cleaned to remove carbon which may build up on their inner perimeter and outer perimeter. The unused ribbon portion 134 and remaining cutout section 116 can be collected for refining/re-melting/re-processing.

In some particular embodiments as illustrated in FIGS. 3A-3E, the inner perimeter and outer perimeter of the annular solder preforms are in the shape of a square. FIG. 3E compares the dimensions of the two annular solder preforms 110, 118. As illustrated here, the first annular solder preform 110 has an outer length Lₒ and an outer width Wₒ of about 0.300 inches. Laser cutting the exterior peripheral edge takes approximately 1.5 seconds. The inner perimeter of the first annular solder preform 110 is defined by the interior peripheral cutting edge, which can have an inner length Lₗ and an inner width Wₗ of about 0.250 inches, i.e. the annular preform itself has a width of about 0.05 inches. Laser cutting the interior peripheral cutting edge also takes approximately 1.5 seconds. Thus, the time to laser cut the first annular solder preform can be about 3 seconds. The exterior and interior peripheral cutting edges are substantially free of burrs and the quality of the preform is not compromised. Continuing, the second annular solder preform 118 has an outer length L₂ and an outer width W₂. The inner length Lₗ of the first annular solder preform is greater than the outer length L₂ of the second annular solder preform, and the inner width Wₗ of the first annular solder preform is greater than the outer width W₂ of the second annular solder preform 118.

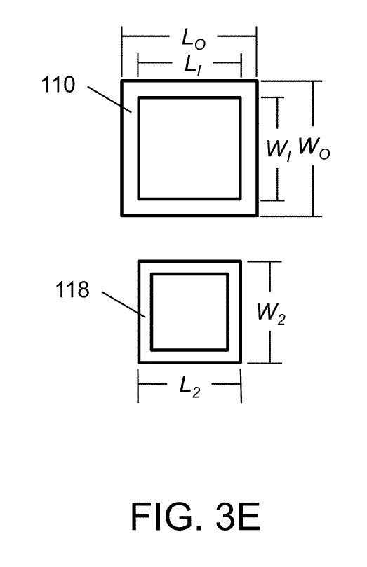

It should be noted that the solder preforms 110, 118 are very thin, and are depicted here as being in the shape of a two-dimensional square annulus. However, it should be understood that the solder preforms are actually three-dimensional objects, albeit with a very small thickness. As illustrated in FIG. 4, each solder preform 110 can be considered as having a first surface 130 and a second surface 132 opposite the first surface. The thickness of the solder preform is illustrated here in the form of a sidewall 134 that has four faces joining the first surface and the second surface together. The first surface and the second surface are generally parallel to each other, or put another way the preform has a constant thickness 135. It should also be understood that the solder preforms are described in terms of their overall shape, and some variation may occur from a strict geometric definition. For example, the square solder preforms of FIGS. 3A-3E may have rounded corners.

Again, the annular preform may be of any desired shape. It is particularly contemplated that the annular preform may be in the shape of a square, a rectangle, or a disc. A square has four sides of equal length and four right angles, while a rectangle has four right angles, and the lengths of adjacent sides can vary. A disc is formed from two concentric circles.

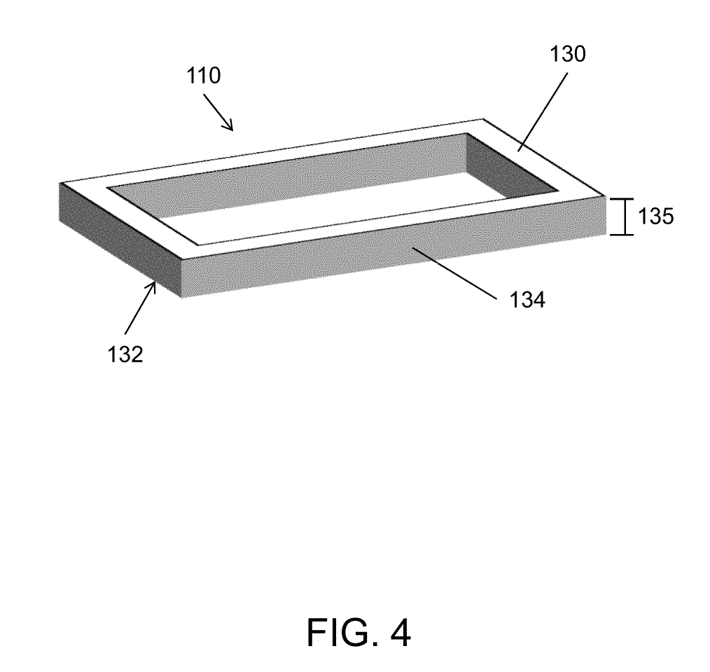

FIGS. 5A-5D illustrate a method for laser cutting multiple disc-shaped annular solder preforms. First, in FIG. 5A, the ribbon of raw material 202 is received in the laser cutting machine. Next, in FIG. 5B, the process of obtaining a first annular solder preform begins by cutting an exterior peripheral cutting edge 212. The exterior peripheral cutting edge defines an outer perimeter of the first annular solder preform. Next, in FIG. 5C, an interior peripheral cutting edge 214 is cut. Interior peripheral cutting edge defines an inner perimeter of the first annular solder preform 210. The interior peripheral cutting edge also defines an outer perimeter of the inner cutout section 216. Again, the exterior cutting edge 212 and the interior cutting edge 214 can be cut in any desired order.

A second annular solder preform is then formed from the inner cutout section 216. As seen in FIG. 5D, a second exterior peripheral cutting edge 220 and a second interior peripheral cutting edge 222 are formed by the laser cutting machine within the inner cutout section 216, with the second annular preform 218 being defined between these two cutting edges 220, 222.

The first annular solder preform 210 and the second annular solder preform 218 are then removed from the ribbon 202. The annular solder preforms 210, 218 can then be cleaned to remove carbon which may build up on their inner perimeter and outer perimeter. The unused ribbon portion 234 and remaining cutout section 216 can be collected for refining/re-melting/re-processing.

The ribbons of raw material 102, 202 and annular solder preforms 110, 118, 210, 218 formed therefrom can be made from a metal alloy such as a lead-based alloy or a lead-free alloy. In particular embodiments, the metal alloy is a gold-tin alloy. Most desirably, the gold-tin alloy is a eutectic composition of about 80 wt % gold and about 20 wt % tin (i.e., 80Au-20Sn). The preforms have a thickness of greater than about 0.001 inches, including about 0.006 inches and up to about 0.010 inches. The preforms can have an outer diameter or outer width of up to 2.500 inches. The solder preforms desirably have a melting temperature of from about 200° C. to about 350° C. In some embodiments, indium is added to the 80Au-20Sn composition to raise its melting point, providing protection against secondary reflow, loss of hermeticity, or critical component shift during the soldering process.

Laser cutting can be performed by any suitable method known in the art, such as with a carbon dioxide laser, a YAG laser or an excimer laser. In some particular embodiments, laser cutting is performed with a carbon dioxide laser. Carbon dioxide lasers typically utilize a gas mixture in which light is amplified by carbon dioxide molecules. Laser cutting is generally achieved by mixing gases (e.g., carbon dioxide, nitrogen, and helium) and feeding the mixture into a first end of a discharge tube. The gas is pumped out a second end of the discharge tube with a mechanical forepump. An electrical discharge is maintained between the first and second end of the tube. Various optic lenses (i.e., mirrors) are used to focus and direct the laser through a nozzle and onto the work piece to be cut. The focused laser beam melts, burns, vaporizes, or blows away the material which comes into contact with the laser beam, resulting in a cutting edge with a high-quality surface finish. The cutting edge is substantially free of raised edges or small pieces of material attached to the cutting edge, commonly referred to as burrs. An ultraviolet (UV) laser can be used.

A computer numerical control (CNC) machine can be used to move the raw material with respect to the generated laser beam or vice versa. A motion control system can also be employed to follow a CNC or G-code of the pattern to be cut from the material. In this regard, any number of various patterns can advantageously be cut to form solder preforms having complex geometries.

The cleaning of the annular solder preforms can be performed by any suitable method such as ultrasonic cleaning, pressure washing, high-temperature outgassing, ultra-pure water rinsing, or drying with compressed clean air. In particular embodiments, the cleaning is performed by ultrasonic cleaning. Ultrasonic cleaning generally refers to a process that uses ultrasound at an appropriate frequency and an appropriate cleaning solvent to clean the preform. The cleaning acts to remove residual debris and contamination which may remain after laser cutting, such as carbon, thereby increasing cleanliness and improving sealing performance of the preform. The ultrasonic frequency can be from about 30 kHz to about 50 kHz. The ultrasonic cleaning may be performed for a period of about 20 minutes to about 40 minutes, including about 30 minutes.

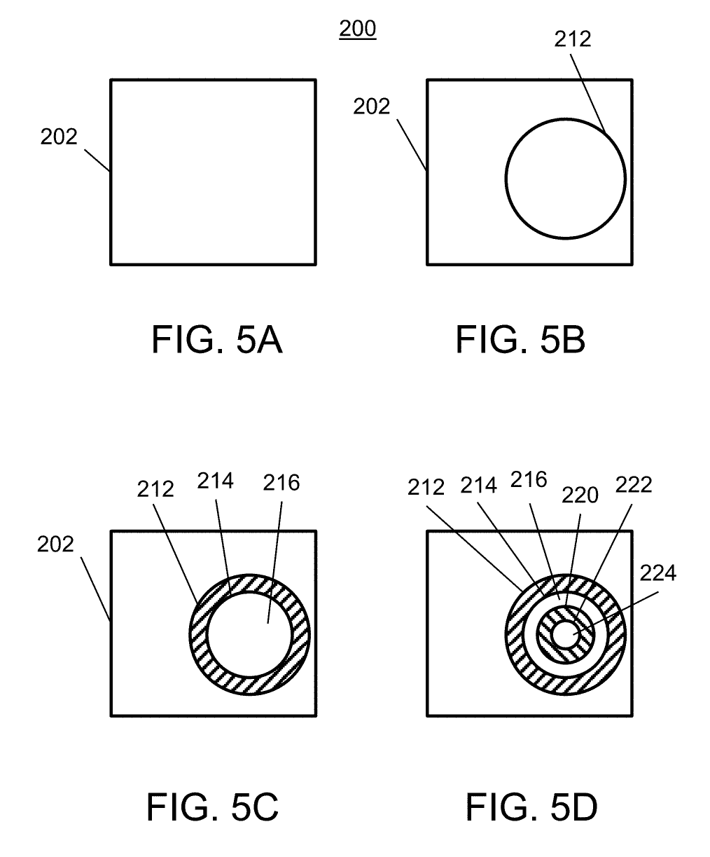

The results of an ultrasonic cleaning process can be seen in FIGS. 6A and 6B. FIG. 6A shows a solder preform before cleaning (left side), wherein carbon build up is shown as a black outline of the interior and exterior peripheral cutting edges. The right side of FIG. 6A shows a solder preform after cleaning, wherein the surface finish has improved in quality and the carbon build up has been eliminated. The solder preforms in FIG. 6A are pictured before performing a melt test. Melting may be performed so that the solder preform can fuse together two components of conventional electronic package, as described in further detail below.

Next, in FIG. 6B, the before cleaning and after cleaning solder preforms of FIG. 6A are pictured after a melt test has been performed on them. The solder preform which did not undergo a cleaning process (left side) exhibits undesirable deformations which can compromise the sealing quality of the preform in subsequent sealing operations. In contrast, the solder preform having undergone a cleaning process (right side) melts in a uniform manner and is substantially free of deformations which might hinder sealing quality or generate cracks.

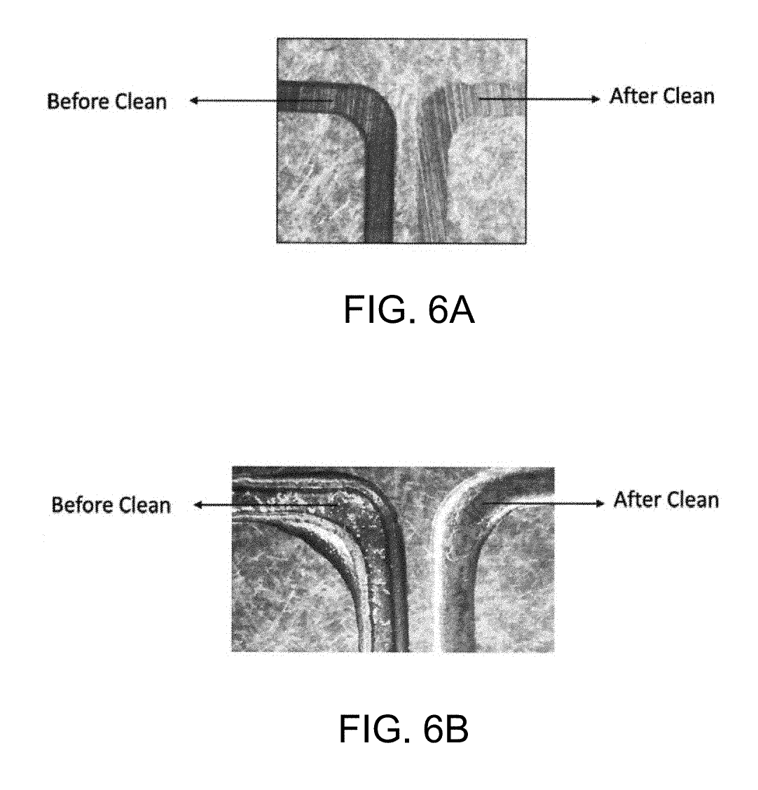

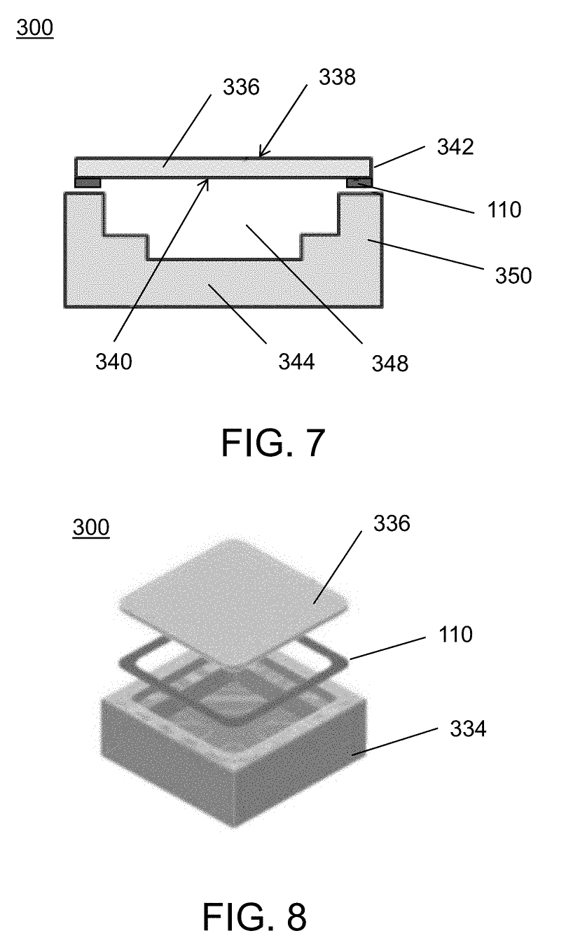

FIG. 7 is a side cross-sectional view of a conventional electronic package that uses an annular solder preform. FIG. 8 is an exploded perspective view showing various aspects of the electronic package. The electronic package 300 is a frame lid assembly formed from an insulating base 344, an annular solder preform 110, and a cover lid or plate 336. The cover lid 336 has a first surface 338, a second surface 340, and sidewall 342. The base is shaped to form a cavity 348 in which an electronic component (e.g. a semiconductor) is mounted. Not shown here are various leads and vias which may be included with the base. The perimeter of the base includes a raised wall 350. When heated, the solder preform melts, and is used to fuse the second surface 340 of the cover lid to the raised wall 350 of the base, hermetically sealing the cavity.

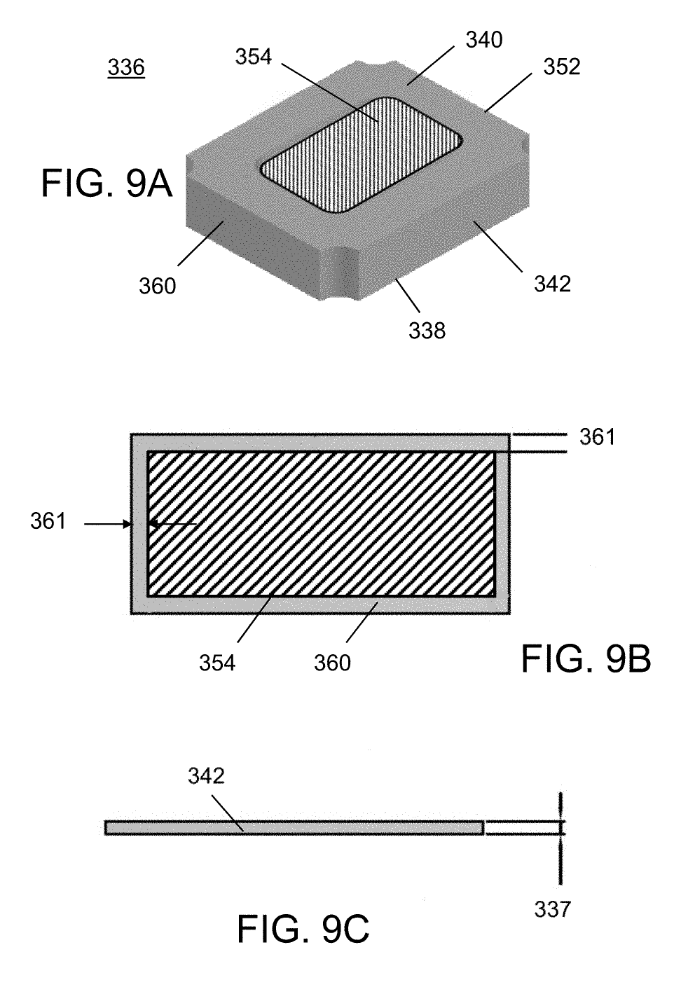

Generally, the annular solder preform can be tack welded to a seal ring on the second surface of the cover lid. FIGS. 9A-9C illustrate various views of a cover lid. FIG. 9A is a magnified perspective view of the cover lid. FIG. 9B is a plan view of the bottom surface of the cover lid (which engages the base of the package). FIG. 9C is a side view of the cover lid.

Referring first to FIG. 9A, the cover lid 336 has a first surface 338 and a second surface 340, with a sidewall 342 joining them together. The second surface is divided into a peripheral area 352 and a central area 354. A layer of metal is present on the peripheral area 352 of the second surface, and a layer of metal is also present on the sidewall 342. The combination of these two layers of metal is referred to herein as a seal ring 360. The metal can be silver, palladium, platinum, nickel, gold, or alloys thereof. In particular embodiments, the seal ring is formed from a non-magnetic metal. The metallizing can be done by sputter deposition, electroplating, thermal spray, chemical vapor deposition (CVD), or any other suitable means. It should be emphasized that the seal ring covers the entire peripheral area of the second surface.

In some desirable embodiments, the seal ring can be formed from a set of sublayers. In such embodiments, there may be two sublayers or three sublayers. In specific embodiments, a nickel sublayer can be laid down first, then a gold sublayer can be laid down over the nickel sublayer. The nickel sublayer serves as a barrier to corrosion, while the gold sublayer provides a readily solderable surface. Each sublayer may have a thickness/depth of 0.001 mm to 0.01 mm (i.e. 1 μm to 10 μm). The seal ring may have a thickness/depth of 0.001 mm to 0.04 mm (i.e. 1 μm to 40 μm).

FIG. 9B is a plan (top) view of the cover lid/plate. FIG. 9C is a side view of the metallized plate. Referring to FIG. 9B, the seal ring is marked with reference numeral 360, and indicated with a clear texture. The central area is marked with reference numeral 354, and indicated with slash lines. The peripheral area is from about 20% to about 35% of the surface area of the second surface of the plate. The central area is from about 65% to about 80% of the surface area of the second surface of the plate. The width of the peripheral area is marked with reference numeral 361. As seen in FIG. 8C, the metal seal ring is also present on the sidewall 342 of the plate. The thickness of the plate is also indicated with reference numeral 337.

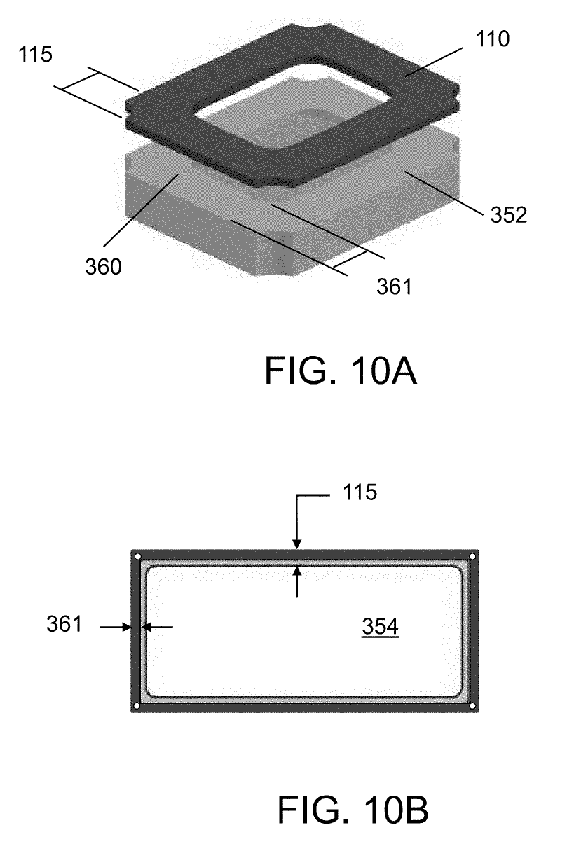

Next, as illustrated in FIG. 10A and FIG. 10B, a solder preform 110 is connected to the seal ring 360. More specifically, the solder preform is laid upon the portion of the seal ring over the peripheral area 352 of the second surface. The solder preform is usually tack welded to the seal ring. FIG. 10A is an exploded view, while FIG. 10B is a plan view of the second surface. The solder preform is annular. The width 115 of the solder preform can be equal to or less than the width 361 of the peripheral area. The width of the solder preform is from about 0.01 inches to about 0.1 inches, as desired. As illustrated in FIG. 10B, the width 115 of the solder preform is less than the width 361 of the peripheral area/seal ring.

As previously mentioned, the solder preform is tack welded to a seal ring located on the second surface of the cover lid/plate. The first annular solder preform is then heated to melt the first annular solder preform and fuse the cover lid to the base. The cover lid 336 is made from a non-metallic material. Exemplary non-metallic materials include beryllium-copper, molybdenum, bronze, glass, an iron-nickel-cobalt alloy (e.g. KOVAR™), an iron-nickel binary alloy (e.g. Alloy 42), or a ceramic selected from the group consisting of alumina (Al2O₃), beryllia (BeO), aluminum nitride (AlN), zirconia toughened alumina (ZTA), SiC, and Si₃N₄. The plate has a thickness (measured between the first surface and the second surface) of about 0.5 millimeters (mm) to about 1 millimeter. In particular embodiments, the plate is made from a non-magnetic material. This may be useful in certain applications where electrical signals/noise can interfere with the electronic component in the package, e.g. in medical imaging applications.

Many advantages accrue in the presently-described methods. Tool and die fabrications are not required, which not only reduces the cost of producing solder preforms, but also saves manpower. In addition, the need to store and maintain tools and dies is eliminated. Laser cutting permits complex cutting designs compared with conventional stamping methods and the lead time is improved. The quality of cuts produced by laser cutting reduces post refining processes, especially deburring since the laser produces burr-free cuts. Moreover, utilization of the ribbon of raw material is maximized.

The present disclosure has been described with reference to exemplary embodiments. Obviously, modifications and alterations will occur to others upon reading and understanding the preceding detailed description. It is intended that the present disclosure be construed as including all such modifications and alterations insofar as they come within the scope of the appended claims or the equivalents thereof.

1. A method of making a solder preform, comprising:
receiving a ribbon of raw material,
forming a first annular solder preform by laser cutting the ribbon along an exterior peripheral cutting edge and an interior peripheral cutting edge; and
cleaning the exterior peripheral cutting edge and the interior peripheral cutting edge of the first annular solder preform.

2. The method of claim 1, further comprising laser cutting a second annular solder preform from an inner cutout section of the first annular solder preform.

3. The method of claim 2, wherein the inner cutout section has an outer perimeter defined by the interior peripheral cutting edge of the first annular solder preform.

4. The method of claim 1, wherein the cleaning is performed by ultrasonically removing carbon on the exterior peripheral cutting edge and the interior peripheral cutting edge of the first annular solder preform.

5. The method of claim 1, wherein the ribbon of raw material is formed from a gold-tin alloy, a lead-based alloy, or a lead-free alloy.

6. The method of claim 5, wherein the gold-tin alloy is about 80 wt % gold and about 20 wt % tin.

7. The method of claim 1, further comprising remelting and refining unused portions of the ribbon.

8. The method of claim 1, wherein the annular solder preform is in the shape of a square, rectangle, or disc.

9. The method of claim 1, wherein the annular solder preform has a melting temperature of from about 200° C. to about 350° C.

10. The method of claim 1, wherein the exterior peripheral cutting edge and the interior peripheral cutting edge are free of burrs.

11. The method of claim 1, a plurality of annular solder preforms are formed from the ribbon of raw material.

12. The method of claim 1, wherein the exterior peripheral cutting edge and the interior peripheral cutting edge of the first annular solder preform are each laser cut from the ribbon in about 1.5 seconds.

13. An annular solder preform prepared by:
receiving a ribbon of raw material;
laser cutting the ribbon along an exterior peripheral cutting edge and an interior peripheral cutting edge; and
cleaning the exterior peripheral cutting edge and the interior peripheral cutting edge to obtain the annular solder preform.

14. The annular solder preform of claim 13, wherein the raw material is a gold-tin alloy.

15. The annular solder preform of claim 13, wherein an outer perimeter of the annular solder preform is in the shape of a square having a length and a width of about 0.3 inches, and an inner perimeter of the annular solder preform is in the shape of a square having a length and a width of about 0.25 inches.

16. The annular solder preform of claim 13, wherein the annular solder preform is in the shape of a square, rectangle, or disc.

17. A method of using an annular solder preform in a frame lid assembly, comprising:
tack welding the annular solder preform to a cover lid;
melting the annular solder preform; and
fusing the cover lid to an insulating base that is shaped to include a cavity using the melted annular solder preform;
wherein the first annular solder preform is made by laser cutting a ribbon of raw material along an exterior peripheral cutting edge and an interior peripheral cutting edge; and
cleaning the exterior peripheral cutting edge and the interior peripheral cutting edge to obtain the annular solder preform.

18. The method of claim 17, wherein the cover lid is made from beryllium-copper, molybdenum, bronze, glass, an iron-nickel-cobalt alloy, or a ceramic selected from the group consisting of alumina (Al₂O₃), beryllia (BeO), aluminum nitride (AlN), zirconia toughened alumina (ZTA), SiC, and Si₃N₄.

19. The method of claim 17, wherein the annular solder preform is formed from a gold-tin alloy containing about 80wt % gold and about 20 wt % tin.

20. A method of making multiple solder preforms from a single ribbon, comprising:
receiving a ribbon of raw material formed from an alloy having about 80 wt % gold and about 20 wt % tin;
forming a first annular solder preform by laser cutting the ribbon along an exterior peripheral cutting edge and an interior peripheral cutting edge, the interior peripheral cutting edge defining an outer perimeter of an inner cutout section; and
laser cutting a second annular solder preform from the inner cutout section of the first annular solder preform.
